(19) United States
(12) Patent Application Publication
(10) Pub. No.: US 2026/0244230 A1
(43) Pub. Date: Aug. 20, 2026

(54) POWER CIRCUIT AND POWER DRIVING DEVICE

(71) Applicant: Device Dynamics Lab Co., Ltd., Zhubei City (TW)

(72) Inventors: Ming-Cheng LIN, Zhubei City (TW); Chao-Ta FAN, Zhubei City (TW); Chih-Kai CHANG, Zhubei City (TW)

(73) Assignee: Device Dynamics Lab Co., Ltd., Zhubei City (TW)

(21) Appl. No.: 19/538,115

(22) Filed: Feb. 12, 2026

(30) Foreign Application Priority Data
Feb. 14, 2025 (TW) 114105576

(51) Int. Cl. G05F 1/52

(52) U.S. Cl. CPC G05F 1/52

(57) ABSTRACT

A power circuit includes a reference terminal, a power supply terminal for receiving a power supply voltage, an input terminal for receiving a driving signal, a power semiconductor device electrically connected between the power supply terminal and the reference terminal, an enhancement-mode transistor, and a depletion-mode transistor. The power semiconductor device has a source terminal and a gate terminal. The enhancement-mode transistor has a drain terminal electrically connected to the gate terminal of the power semiconductor device, and a gate terminal and a source terminal that are electrically connected to the input terminal. The depletion-mode transistor has a drain terminal electrically connected to the gate terminal of the power semiconductor device, a gate terminal electrically connected to the source terminal of the power semiconductor device, and a source terminal electrically connected to the input terminal.

### CROSS-REFERENCE TO RELATED APPLICATION

This application claims priority to Taiwanese Invention Patent Application No. 114105576, filed on Feb. 14, 2025, the entire disclosure of which is incorporated by reference herein.

### FIELD

The disclosure relates to a power circuit and a power driving device.

### BACKGROUND

Third generation semiconductor (also known as the wide-bandgap semiconductor) materials include silicon carbide (SiC) and gallium nitride (GaN). The third generation semiconductor materials have favorable characteristics, such as relatively high carrier mobility and a relatively large bandgap. For example, a semiconductor device that is manufactured using GaN technology (also known as a GaN device) may have a figure of merit (FOM) that is 5 to 10 times higher than an FOM of a semiconductor device that is manufactured using silicon technology. As a result, the third generation semiconductor materials may be employed to manufacture devices for more advanced applications such as high-voltage power semiconductor devices and high-frequency communication devices.

Referring to FIG. 1, a conventional power driving device includes a power semiconductor device 11 and a driver 12. The power semiconductor device 11 and the driver 12 belong to different packages of the conventional power driving device, and are separated by the dashed lines in FIG. 1. The power semiconductor device 11 has a gate terminal. The driver 12 is electrically connected to a first power supply terminal for receiving a first power supply voltage (Vcc), and is configured to receive an input signal (Vin), and output a driving signal (Vout) to the gate terminal of the power semiconductor device 11. The power semiconductor device 11 is electrically connected between a second power supply terminal and a reference terminal for respectively receiving a second power supply voltage (Vds) and a reference voltage (Vss) therefrom. The power semiconductor device 11 is configured to switch between a conducting state and a non-conducting state based on the driving signal (Vout) received from the driver 12. In high-frequency applications, rapid switching of the power semiconductor device 11 may cause noise to be formed at the gate terminal of the power semiconductor device 11, which may interfere with the driving signal (Vout). This in turn may cause the power semiconductor device 11 to malfunction.

A conventional way of addressing the above-mentioned problem is by adjusting parameters during manufacturing process of the power semiconductor device 11 to increase a threshold voltage of the power semiconductor device 11. When the threshold voltage of the power semiconductor device 11 is increased, an ability of the power semiconductor device 11 to overcome noise (i.e., noise of the driving signal (Vout)) is also increased. However, a disadvantage of this conventional way is that it may reduce a reverse conduction efficiency of the power semiconductor device 11.

Another conventional way of addressing the above-mentioned problem is shown in FIG. 2, illustrating another conventional power driving device. The another conventional power driving device includes a driving circuit 13 disposed at the gate terminal of the power semiconductor device 11 of the conventional power driving device through integration or co-packaging to form an integrated circuit as shown in the box drawn with dashed lines in FIG. 2. By controlling an operation of the driving circuit 13, a threshold voltage of the integrated circuit (as taken from the side of the driver 12) may be increased. Additionally, the driving circuit 13 serves as an intermediary for transmitting the driving signal (Vout), thereby reducing an impact of noise of the driving signal (Vout). However, adding the driving circuit 13 requires an additional power supply terminal for supplying a third power supply voltage (Vdd) to the driving circuit 13, which may require an external drive circuit 14 to maintain the stability of the third power supply voltage (Vdd). Moreover, the integrated circuit of the power semiconductor device 11 will also require an additional pin to connect to the external drive circuit 14. As a result, this another conventional way not only complicates control of the operation of the another conventional power driving device, but also occupies a significant amount of space both inside and outside of the integrated circuit of the power semiconductor device 11 and requires the additional pin, thereby increasing overall costs.

### SUMMARY

Therefore, an object of the disclosure is to provide a power circuit and a power driving device that can alleviate at least one of the drawbacks of the prior art.

According to an aspect of the disclosure, the power circuit includes a reference terminal, a power supply terminal for receiving a power supply voltage, an input terminal for receiving a driving signal, a power semiconductor device electrically connected between the power supply terminal and the reference terminal, an enhancement-mode (E-mode) transistor, and a depletion-mode (D-mode) transistor. The power semiconductor device has a source terminal and a gate terminal. The E-mode transistor has a drain terminal electrically connected to the gate terminal of the power semiconductor device, and a gate terminal and a source terminal that are electrically connected to the input terminal. The D-mode transistor has a drain terminal electrically connected to the gate terminal of the power semiconductor device, a gate terminal electrically connected to the source terminal of the power semiconductor device, and a source terminal electrically connected to the input terminal.

According to another aspect of the disclosure, the power driving device includes a reference terminal, a first power supply terminal for receiving a first power supply voltage, a second power supply terminal for receiving a second power supply voltage, an input terminal for receiving an input signal, a driver electrically connected to the second power supply terminal and the reference terminal, and a power circuit. The driver is further electrically connected to the input terminal for receiving the input signal therefrom, and is configured to output a driving signal that corresponds to the input signal thus received. The power circuit includes a power semiconductor device, an enhancement-mode (E-mode) transistor, and a depletion-mode (D-mode) transistor. The power semiconductor device is electrically connected between the first power supply terminal and the reference terminal, and has a source terminal and a gate terminal. The E-mode transistor has a drain terminal electrically connected to the gate terminal of the power semiconductor device, and a gate terminal and a source terminal that are electrically connected to the driver for receiving the driving signal therefrom. The D-mode transistor has a drain terminal electrically connected to the gate terminal of the power semiconductor device, a gate terminal electrically connected to the source terminal of the power semiconductor device, and a source terminal electrically connected to the driver for receiving the driving signal therefrom.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a circuit block diagram illustrating a conventional power driving device.

FIG. 2 is a circuit block diagram illustrating another conventional power driving device in use with an external drive circuit.

FIG. 3 is a circuit block diagram illustrating a power driving device according to a first embodiment of the disclosure.

FIG. 4 shows transfer characteristics respectively of a power semiconductor device of the conventional power driving device of FIG. 1, and a power circuit of the power driving device according to the first embodiment of the disclosure.

FIG. 5 shows reverse conduction characteristics respectively of the power semiconductor device of the conventional power driving device of FIG. 1, and the power circuit of the power driving device according to the first embodiment of the disclosure.

FIG. 6 is a circuit block diagram illustrating the power driving device according to a second embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

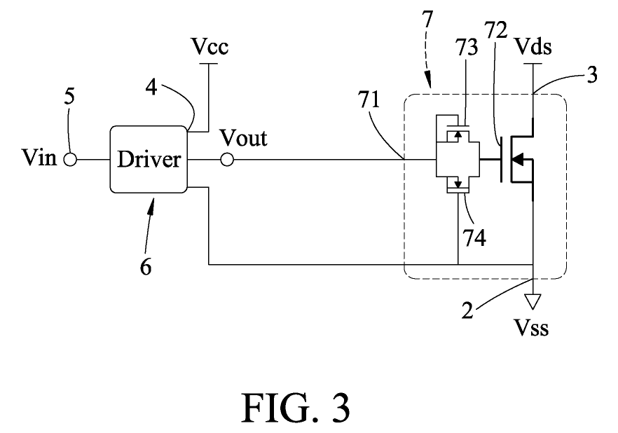

Referring to FIG. 3, a power driving device according to a first embodiment of the present disclosure includes a reference terminal 2, a first power supply terminal 3, a second power supply terminal 4, a first input terminal 5, a driver 6, and a power circuit 7.

The reference terminal 2 is configured to receive a reference voltage (Vss). In this embodiment, the reference terminal 2 is electrically connected to ground (GND) (not shown), which is at a reference voltage (Vss) of 0 Volts, but the disclosure is not limited to such.

The first power supply terminal 3 is configured to receive a first power supply voltage (Vds). In this embodiment, the first power supply terminal 3 is electrically connected to a first power supply (not shown) for receiving the first power supply voltage (Vds) therefrom, but the disclosure is not limited to such.

The second power supply terminal 4 is configured to receive a second power supply voltage (Vcc). In this embodiment, the second power supply terminal 4 is electrically connected to a second power supply (not shown) for receiving the second power supply voltage (Vcc) therefrom, but the disclosure is not limited to such.

The first input terminal 5 is configured to receive an input signal (Vin). In this embodiment, the first input terminal 5 is electrically connected to a control circuit (not shown) for receiving the input signal (Vin). In one embodiment, the input signal (Vin) is in a form of a pulse signal, but the disclosure is not limited to such.

The driver 6 is electrically connected to the second power supply terminal 4 and the reference terminal 2. The driver 6 is further electrically connected to the first input terminal 5 for receiving the input signal (Vin) therefrom, and is configured to output a driving signal (Vout) that corresponds to the input signal (Vin) thus received. In some embodiments, the driver 6 may be embodied as a gate driver configured to amplify the input signal (Vin) and output the driving signal (Vout) with a phase corresponding to that of the input signal (Vin).

The power circuit 7 is electrically connected to the reference terminal 2 and the first power supply terminal 3, and includes a second input terminal 71, a power semiconductor device 72, a first enhancement-mode (E-mode) transistor 73, and a depletion-mode (D-mode) transistor 74.

The second input terminal 71 is electrically connected to the driver 6, and is configured to receive the driving signal (Vout) therefrom.

In the first embodiment, the power semiconductor device 72 is exemplified by a gallium nitride (GaN) power semiconductor device, and hereinafter will be referred to as “the GaN power semiconductor device 72”. The GaN power semiconductor device 72 is electrically connected between the first power supply terminal 3 and the reference terminal 2. Specifically, the GaN power semiconductor device 72 has a drain terminal electrically connected to the first power supply terminal 3, a source terminal electrically connected to the reference terminal 2, and a gate terminal. In one embodiment, the GaN power semiconductor device 72 is exemplified as an E-mode GaN high electron mobility transistor (HEMT).

The first E-mode transistor 73 has a drain terminal electrically connected to the gate terminal of the GaN power semiconductor device 72, a gate terminal and a source terminal that are electrically connected to the second input terminal 71 for receiving the driving signal (Vout) from the driver 6. In one embodiment, the first E-mode transistor 73 is exemplified as the E-mode GaN HEMT. The first E-mode transistor 73 is configured to switch between a conducting state and a non-conducting state based on the driving signal (Vout) received at the gate terminal of the first E-mode transistor 73.

The D-mode transistor 74 has a drain terminal electrically connected to the gate terminal of the GaN power semiconductor device 72, a gate terminal electrically connected to the source terminal of the GaN power semiconductor device 72, and a source terminal electrically connected to the second input terminal 71 for receiving the driving signal (Vout) from the driver 6. In one embodiment, the D-mode transistor 74 is exemplified as a D-mode GaN HEMT. The D-mode transistor 74 is configured to switch between a conducting state and a non-conducting state based on the driving signal (Vout) received at the source terminal of the D-mode transistor 74.

In some embodiments, since the GaN power semiconductor device 72 is a power device, a size of the GaN power semiconductor device 72 is relatively bigger so as to be able to support enhanced voltage and current flowing through the GaN power semiconductor device 72 as compared to sizes of the first E-mode transistor 73 and the D-mode transistor 74, which do not need to support the enhanced voltage. Therefore, the first E-mode transistor 73 and the D-mode transistor 74 may be implemented as logic devices. That is to say, the size of the first E-mode transistor 73 and the size of the D-mode transistor 74 are smaller than the size of the GaN power semiconductor device 72, which allows the first E-mode transistor 73 and the D-mode transistor 74 to be implemented using transistors that fulfil the minimum design rules of the semiconductor fabrication process. In some embodiments, the GaN power semiconductor device 72, the first E-mode transistor 73 and the D-mode transistor 74 are integrated and formed on a same chip. The GaN power semiconductor device 72 is configured to switch between a conducting state and a non-conducting state based on the driving signal (Vout) received from the driver 6 through the first E-mode transistor 73 or the D-mode transistor 74.

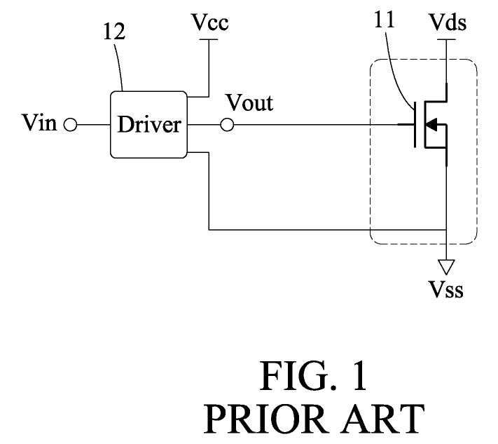

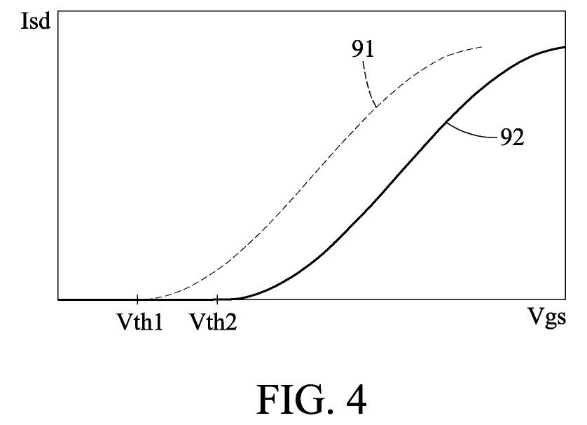

Referring to FIGS. 3, 4, and 5, an example where the driving signal (Vout) is a pulse signal having a high voltage level, and a low voltage level that is lower than the high voltage level is provided. When the driving signal (Vout) is at the high voltage level, the first E-mode transistor 73 switches into the conducting state, where a threshold voltage of the first E-mode transistor 73 is taken, for example, as 1.5 Volts, and the D-mode transistor 74 switches into the non-conducting state, where a threshold voltage of the D-mode transistor 74 is taken, for example, as -0.8 Volts. Since the gate terminal and the source terminal of the first E-mode transistor 73 are electrically connected to each other, the first E-mode transistor 73 forms a diode-like structure with characteristics of a diode, and the diode-like structure has a threshold voltage of, for example, 1.5 Volts. The threshold voltage of the diode-like structure (e.g., 1.5 Volts) may superimpose on a threshold voltage of the GaN power semiconductor device 72 (e.g., 1.5 Volts), which may cause an overall threshold voltage (i.e., a threshold voltage of the power circuit 7 or a sum of the threshold voltage of the diode-like structure and the threshold voltage of the GaN power semiconductor device 72) taken from the side of the second input terminal 71 to increase. In this case, the overall threshold voltage is taken as the sum of 1.5 Volts (i.e., the threshold voltage of the diode-like structure) and 1.5 Volts (i.e., the threshold voltage of the GaN power semiconductor device 72), equaling to 3 Volts. For example, in FIG. 4, transfer characteristics respectively of the power semiconductor device 11 of a conventional power driving device of FIG. 1, and the power circuit 7 of the power driving device of this disclosure are presented. The transfer characteristics are presented in a line graph having a y-axis that is denoted by the drain-to-source current (Ids) and an x-axis that is denoted by the gate-to-source voltage (Vgs). In the line graph, plot 91 denotes the transfer characteristic of the power semiconductor device 11 of the conventional power driving device (i.e., without the first E-mode transistor 73) of FIG. 1, and plot 92 denotes the transfer characteristic of the power circuit 7 (i.e., with the first E-mode transistor 73) of this disclosure. It can be seen from FIG. 4 that the threshold voltage (Vth2) of the power circuit 7 (3 Volts in this example) of the power driving device of this disclosure is higher than the threshold voltage (Vth1) of the power semiconductor device 11 (1.5 Volts in this example) of the conventional power driving device in FIG. 1. The difference in voltage between the threshold voltage (Vth1) and the threshold voltage (Vth2) (i.e., 1.5 Volts) lies in the threshold voltage of the diode-like structure formed in the first E-mode transistor 73 that has the threshold voltage of 1.5 Volts and that is present in the power circuit 7 of the power driving device of this disclosure. Therefore, the arrangements of the power driving device of this disclosure is able to increase the threshold voltage of the power circuit 7, thereby increasing an ability of the power driving device of this disclosure to overcome noises of the driving signal (Vout).

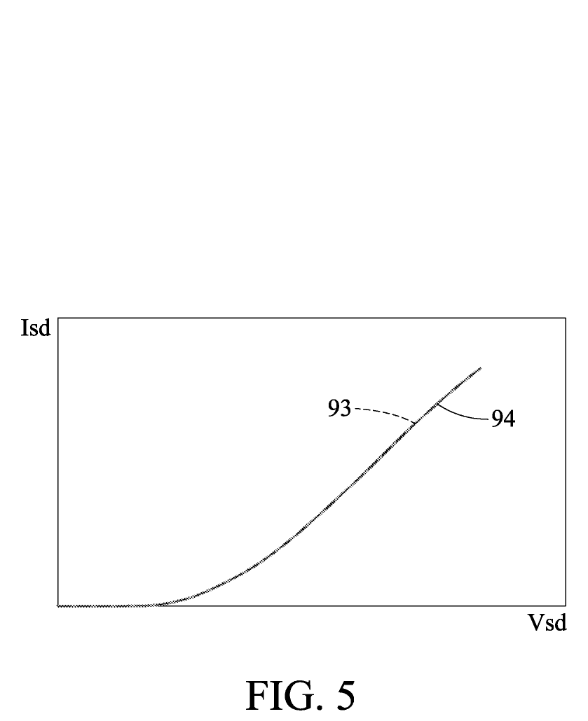

When the driving signal (Vout) is at the low voltage level, the first E-mode transistor 73 switches into the non-conducting state, and the D-mode transistor 74 switches into the conducting state, which provides a discharge path for an input capacitance of the gate terminal of the GaN power semiconductor device 72. That is to say, charges of the input capacitance may be discharged through the drain terminal and the source terminal of the D-mode transistor 74 when the D-mode transistor 74 is in the conducting state. For example, in FIG. 5, reverse conduction characteristics respectively of the power semiconductor device 11 of the conventional power driving device of FIG. 1 and the power circuit 7 of the power driving device of this disclosure are presented. The reverse conduction characteristics are presented in a line graph having a y-axis that is denoted by the source-to-drain current (Isd) and an x-axis that is denoted by the source-to-drain voltage (Vsd). In the line graph, plot 93 denotes the reverse conduction characteristic of the power semiconductor device 11 of the conventional power driving device of FIG. 1, and plot 94 denotes the reverse reduction characteristic of the power circuit 7 of this disclosure. It can be seen from FIG. 5 that the plot 93 and the plot 94 overlap each other entirely, which indicates that the reverse conduction characteristic of the power circuit 7 of this disclosure is the same as the reverse conduction characteristic of the power semiconductor device 11 of the conventional power driving device in FIG. 1. That is to say, by virtue of the power circuit 7 providing the discharge path through the D-mode transistor 74, the power circuit 7 of this disclosure is able to achieve an increase in the overall threshold voltage of the power circuit 7 without affecting the reverse conduction efficiency of the power circuit 7.

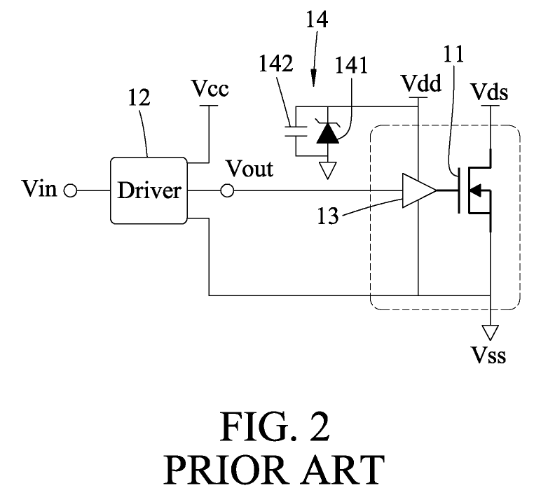

As can be seen from the examples above, by virtue of integrating the first E-mode transistor 73 with the GaN power semiconductor device 72, and electrically connecting the gate terminal and the source terminal of the first E-mode transistor 73 to each other, the overall threshold voltage taken from the side of the second input terminal 71 may be increased, thereby increasing the ability of the power driving device of this disclosure to overcome the noise of the driving signal (Vout). Furthermore, by virtue of the D-mode transistor 74 providing the discharge path, the power driving device of this disclosure is able to achieve the increase in the overall threshold voltage without affecting the reverse reduction efficiency. In addition, the power driving device of this disclosure (as compared to the conventional power driving device in FIG. 2) is able to overcome noise interference without requiring an external driving circuit and an additional power supply for the external driving circuit, and without affecting the reverse conduction efficiency. Therefore, the power driving device of this disclosure may have better market sales potential than conventional power driving devices.

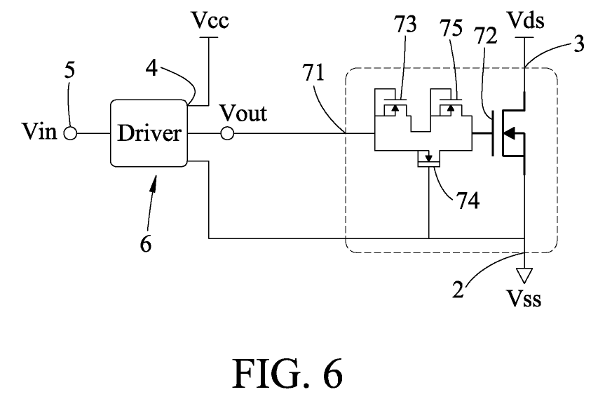

Referring to FIG. 6, the power driving device according to a second embodiment of the present disclosure is presented. The second embodiment is similar to the first embodiment, and only differences between the second embodiment and the first embodiment will be illustrated below for the sake of brevity.

In the second embodiment, the power driving device further includes a second E-mode transistor 75 electrically connected between the drain terminal of the first E-mode transistor 73 and the gate terminal of the GaN power semiconductor device 72. In some embodiments, the second E-mode transistor 75 may be exemplified as an E-mode GaN HEMT.

The second E-mode transistor 75 includes a drain terminal electrically connected to the gate terminal of the GaN power semiconductor device 72, and a gate terminal and a source terminal that are electrically connected to each other and to the drain terminal of the first E-mode transistor 73. Similar to the first E-mode transistor 73, the second E-mode transistor 75 forms a diode-like structure with characteristics of a diode, and the diode-like structure has a threshold voltage of, for example, 1.5 Volts. By virtue of this arrangement, the threshold voltage of the second E-mode transistor 75 may superimpose with the threshold voltage of the first E-mode transistor 73, and may further superimpose with the threshold voltage of the GaN power semiconductor device 72, thereby further increasing the overall threshold voltage (i.e., the threshold voltage of the power circuit 7) taken from the side of the second input terminal 71. The further increase in the overall threshold voltage further increases the ability of the power driving device of this disclosure to overcome noise.

In some embodiments, the second E-mode transistor 75 may be implemented as a logic device. That is to say, a size of the second E-mode transistor 75 is smaller than the size of the GaN power semiconductor device 72, which allows the second E-mode transistor 75 to be implemented using a transistor that fulfils the minimum design rules of the semiconductor fabrication process. In some embodiments, the second E-mode transistor 75, the GaN power semiconductor device 72, the first E-mode transistor 73, and the D-mode transistor 74 are integrated and formed on a same chip.

By virtue of the above arrangements, the second embodiment is also able to achieve an increase in the overall threshold voltage of the power circuit 7, which increases the ability of the power driving device of this disclosure to overcome noise, without affecting the reverse conduction efficiency (i.e., by having the D-mode transistor 74 that provides the discharge path). Furthermore, by electrically connecting the second E-mode transistor 75 in series with the first E-mode transistor 73, the overall threshold voltage of the power circuit 7 is further increased.

In sum, the power driving device of this disclosure is able to achieve an increase in the overall threshold voltage of the power circuit 7, without affecting the reverse conduction efficiency of the power driving device of this disclosure, and without requiring the external driving circuit and the additional power supply for the external driving circuit.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A power circuit, comprising:
a reference terminal;
a power supply terminal for receiving a power supply voltage;
an input terminal for receiving a driving signal;
a power semiconductor device electrically connected between said power supply terminal and said reference terminal, and having a source terminal and a gate terminal;
a first enhancement-mode (E-mode) transistor having a drain terminal electrically connected to said gate terminal of said power semiconductor device, and a gate terminal and a source terminal that are electrically connected to said input terminal; and
a depletion-mode (D-mode) transistor having a drain terminal electrically connected to said gate terminal of said power semiconductor device, a gate terminal electrically connected to said source terminal of said power semiconductor device, and a source terminal electrically connected to said input terminal.

2. The power circuit as claimed in claim 1, wherein said first E-mode transistor is an E-mode gallium nitride (GaN) high electron mobility transistor (HEMT), and said D-mode transistor is a D-mode GaN HEMT.

3. The power circuit as claimed in claim 1, further comprising:
a second E-mode transistor electrically connected between said drain terminal of said first E-mode transistor and said gate terminal of said power semiconductor device.

4. The power circuit as claimed in claim 3, wherein said second E-mode transistor has a drain terminal electrically connected to said gate terminal of said power semiconductor device, and a gate terminal and a source terminal that are electrically connected to said drain terminal of said first E-mode transistor.

5. The power circuit as claimed in claim 3, wherein said second E-mode transistor is an E-mode GaN HEMT.

6. The power circuit as claimed in claim 1, wherein said power semiconductor device is a GaN power semiconductor device.

7. The power circuit as claimed in claim 1, wherein said power semiconductor device, said first E-mode transistor and said D-mode transistor are formed on a same chip.

8. A power driving device, comprising:
a reference terminal;
a first power supply terminal for receiving a first power supply voltage;
a second power supply terminal for receiving a second power supply voltage;
an input terminal for receiving an input signal;
a driver electrically connected to said second power supply terminal and said reference terminal, further electrically connected to said input terminal for receiving the input signal therefrom, and configured to output a driving signal that corresponds to the input signal thus received; and
a power circuit that includes
a power semiconductor device electrically connected between said first power supply terminal and said reference terminal, and having a source terminal and a gate terminal,
a first enhancement-mode (E-mode) transistor having a drain terminal electrically connected to said gate terminal of said power semiconductor device, and a gate terminal and a source terminal that are electrically connected to said driver for receiving the driving signal therefrom, and
a depletion-mode (D-mode) transistor having a drain terminal electrically connected to said gate terminal of said power semiconductor device, a gate terminal electrically connected to said source terminal of said power semiconductor device, and a source terminal electrically connected to said driver for receiving the driving signal therefrom.

9. The power driving device as claimed in claim 8, wherein said first E-mode transistor is an E-mode gallium nitride (GaN) high electron mobility transistor (HEMT), and said D-mode transistor is a D-mode GaN HEMT.

10. The power driving device as claimed in claim 8, further comprising:
a second E-mode transistor electrically connected between said drain terminal of said first E-mode transistor and said gate terminal of said power semiconductor device.

11. The power driving device as claimed in claim 10, wherein said second E-mode transistor includes a drain terminal electrically connected to said gate terminal of said power semiconductor device, and a gate terminal and a source terminal that are electrically connected to said drain terminal of said first E-mode transistor.

12. The power driving device as claimed in claim 10, wherein said second E-mode transistor is an E-mode GaN HEMT.

13. The power driving device as claimed in claim 8, wherein said power semiconductor device is a GaN power semiconductor device.

14. The power driving device as claimed in claim 8, wherein said power semiconductor device, said first E-mode transistor and said D-mode transistor are formed on a same chip.
